(19) United States
(12) Patent Application Publication
(10) Pub. No.: US 2026/0164624 A1
(43) Pub. Date: Jun. 11, 2026

(54) POWER CONVERSION DEVICE

(71) Applicants: HYUNDAI MOTOR COMPANY, Seoul (KR); KIA CORPORATION, Seoul (KR)

(72) Inventor: Jun Seong Kang, Hwaseong-si (KR)

(73) Assignees: HYUNDAI MOTOR COMPANY, Seoul (KR); KIA CORPORATION, Seoul (KR)

(21) Appl. No.: 19/225,671

(22) Filed: Jun. 2, 2025

(30) Foreign Application Priority Data
Dec. 6, 2024 (KR) 10-2024-0180480

(51) Int. Cl. H05K 7/20

(52) U.S. Cl. CPC H05K 7/2089

(57) ABSTRACT

A power conversion device is provided. The power conversion device includes a housing with a power conversion component built into an internal space thereof, a chamber provided to be separated from the internal space of the housing, a filter that is coupled to one side of the chamber and configured to block moisture and foreign substances from entering the chamber from the outside, and a valve provided between the internal space of the housing and the chamber to block the communication between the internal space of the housing and the outside and configured to be selectively opened and closed of a differential pressure between the internal space of the housing and the chamber.

### CROSS-REFERENCE TO RELATED APPLICATION(S)

The present application claims priority to and the benefit of Korean Patent Application No. 10-2024-0180480, filed on Dec. 6, 2024, the entire contents of which are incorporated herein by reference.

### TECHNICAL FIELD

Various embodiments of the present disclosure relate to a power conversion device capable of securing the durability of a power conversion component by incorporating a valve that opens (e.g., only) under (e.g., specific or predetermined) pressure conditions between the power conversion component and the external environment.

### BACKGROUND

Power conversion devices such as inverters are devices that perform AC/DC conversion, DC/AC conversion, and power control functions, and include various power conversion components. When the built-in power conversion components of these devices operate, heat is generated during the power conversion process, which increases the temperature inside the device, resulting in increased pressure and air being discharged to the outside. On the other hand, when the power conversion components do not operate, the internal temperature decreases and the pressure lowers, causing air to flow in from the outside.

As this introduction and discharge of air is repeated, temperature changes inside the device may cause moisture to condense. That is, moisture evaporation due to the high temperature inside the device is cooled when external air is introduced, resulting in the formation of condensation. This condensation may cause damage to power conversion components and surrounding circuits thereof, which may be the main cause of device performance degradation and failure.

Condensation may have a negative impact on the reliability and durability of electronic devices and may threaten the operational safety of power conversion components. Therefore, a technology to effectively manage temperature and pressure changes inside the power conversion device and prevent damage to the power conversion component by preventing condensation may be useful to improve the reliability of the power conversion device and improve (e.g., optimize) the performance of the entire system.

Various approaches have been attempted to address the condensation in various types of power conversion devices, but most approaches are limited or expensive and thus have limitations in practicality. For example, there have been attempts to control temperature and pressure through air circulation systems, but these systems incur additional costs for installation and maintenance and increase the size of the power conversion device. In addition, other attempts do not respond immediately to temperature changes and have limitations in preventing condensation before it occurs.

To overcome these limitations, there is a growing demand for efficient technologies to control temperature and pressure inside power conversion devices.

The matters described as the background technology above are for the purpose of enhancing understanding of the background of the present disclosure.

### SUMMARY

Accordingly, the present disclosure is intended to provide a power conversion device with enhanced waterproofing and dustproofing effects by installing a one-way or two-way valve that opens (e.g., only) in response to a pressure of an internal space containing a power conversion component or a chamber communicating with the outside reaching no less than a (e.g., specific or predetermined) pressure condition, which allows fluid to flow between the two, thereby preventing damage to the power conversion component.

The present disclosure is not limited to the technical problems mentioned herein, and other technical problems not mentioned may be understood by a person having ordinary skills in the technical field to which the present disclosure belongs from the description herein.

In order to achieve the objectives of the present disclosure, a power conversion device of the present disclosure may include a housing with a power conversion component built into an internal space thereof, a chamber provided to be separated from the internal space of the housing, a filter that is coupled to a (e.g., one) side of the chamber and configured to block moisture and foreign substances from entering the chamber from the outside, and a valve provided between the internal space of the housing and the chamber to block communication between the internal space of the housing and the outside and configured to be selectively opened and closed based on (e.g., of) a differential pressure between the internal space of the housing and the chamber.

In the power conversion device of the present disclosure, the valve may include at least one elastic body, wherein the elastic body may be configured to operate under conditions different from one another depending on the differential pressure between the internal (e.g., inner) space of the housing and the chamber, thereby allowing temporary communication between the inner space of the housing and the outside.

In the power conversion device of the present disclosure, the valve may be configured to be operated by an elastic force of the elastic body, such that in response that the elastic force is greater than the differential pressure, the elastic body may expand and close the valve, whereas in response that the elastic force is less than the differential pressure, the elastic body may contract and open the valve.

In the power conversion device of the present disclosure, the valve may include a plurality of valves, each of which allows fluid to flow in (e.g., only) one direction, whereas the valves different from one another permit the fluid to flow in different directions, respectively.

In the power conversion device of the present disclosure, each of the plurality of valves may be provided with an elastic body, wherein each elastic body may contract in a different direction, thereby causing each of the valves to open in a different direction.

In the power conversion device of the present disclosure, the valve may include a first valve and a second valve, each including a first elastic body and a second elastic body, respectively, that may contract in different directions, thereby causing the first valve and the second valve to open in different directions.

In the power conversion device of the present disclosure, in response that the first valve is opened, the fluid may flow from the chamber toward the internal space of the housing, and in response that the second valve is opened, the fluid may flow from the internal space of the housing toward the chamber.

In the power conversion device of the present disclosure, in response that the differential pressure between the chamber and the internal space of the housing is greater than an elastic force of the first elastic body, the first valve may open, and in response that the differential pressure is greater than an elastic force of the second elastic body, the second valve may open.

In the power conversion device of the present disclosure, the first valve and the second valve may have different differential pressures at which they open because elastic forces of the first elastic body and the second elastic body may differ from each other.

In the power conversion device of the present disclosure, the valve may be an integral valve capable of opening in opposite directions, with a plurality of elastic bodies provided inside, each having a different direction of contraction.

In the power conversion device of the present disclosure, the integral valve may be provided with an introduction elastic body and a discharge elastic body, such that in response that the introduction elastic body contracts, fluid may flow from the chamber toward the internal space of the housing, whereas in response that the discharge elastic body contracts, the fluid may flow from the internal space of the housing toward the chamber.

In the power conversion device of the present disclosure, the introduction elastic body and the discharge elastic body may contract at (e.g., of) differential pressures between the internal space of the housing and the chamber, and due to different elastic forces thereof, the differential pressures at which the introduction elastic body and the discharge elastic body contract may differ.

In the power conversion device of the present disclosure, in response that the differential pressure between the chamber and the internal space of the housing is greater than an elastic force of the introduction elastic body, the introduction elastic body may contract, allowing the fluid to flow into the internal space of the housing, whereas in response that the differential pressure is greater than the discharge elastic body, an elastic force of the discharge elastic body may contract, allowing the fluid to flow into the chamber.

In the power conversion device of the present disclosure, a regulator may be provided inside the integral valve, a (e.g., one) side of the regulator may be in contact with the introduction elastic body fixed to the integral valve, an opposite side may be connected to the chamber, and the discharge elastic body may be included inside the regulator.

In the power conversion device of the present disclosure, the regulator may further include an adjustment hole provided in a direction facing the inner space of the housing to allow the fluid inside the integral valve to enter and exit the regulator, and an adjustment ball provided inside the regulator, in contact with the adjustment hole, to open and close the adjustment hole by contraction of the introduction elastic body or the discharge elastic body, wherein the discharge elastic body may have an (e.g., one) end connected to the adjustment ball and an opposite end fixed to the inside of the regulator.

In the power conversion device of the present disclosure, in response that the fluid inside the integral valve is introduced into the regulator, the adjustment ball may pressurize the discharge elastic body, causing it to contract.

In the power conversion device of the present disclosure, in response that the introduction elastic body contracts, the adjustment hole may be closed by the adjustment ball, whereas in response that the discharge elastic body contracts, the adjustment hole may be opened.

In the power conversion device of the present disclosure, in response that the differential pressure between the chamber and the internal space of the housing is less than the elastic force of the discharge elastic body, the adjustment hole may be closed by the adjustment ball, whereas in response that the differential pressure between the chamber and the internal space of the housing is greater than the elastic force of the discharge elastic body, the discharge elastic body may contract and the adjustment hole may be opened.

In the power conversion device of the present disclosure, the filter may communicate with the outside, and as outside air is introduced into the chamber through the filter, a pressure difference may be provided between the inner space of the housing and the chamber.

In the power conversion device of the present disclosure, the chamber may be located inside the housing, the filter may be coupled to a (e.g., one) side of the chamber facing the outside, and the valve may be coupled to an opposite side of the chamber facing the internal space of the housing.

As described above, of the power conversion device of the present disclosure, damage to the power conversion component may be prevented as the condensation (e.g., phenomenon) is prevented, and the durability of the power conversion component may be improved as the waterproof and dustproof capabilities are increased.

The improvements (e.g., effects) that may be obtained from the present disclosure are not limited to the improvements mentioned above, and other improvements that are not mentioned may be understood by those skilled in the art to which the present disclosure belongs from the description herein.

### BRIEF DESCRIPTION OF THE DRAWINGS

The above and other objectives, features, and other advantages of the present disclosure may be understood from the detailed description when taken in conjunction with the accompanying drawings.

FIG. 1 is a drawing showing a power conversion device according to an embodiment.

FIG. 2 is an enlarged drawing of part A of the power conversion device according to an embodiment shown in FIG. 1.

FIG. 3 is a drawing showing a power conversion device according to another embodiment.

### DETAILED DESCRIPTION

In describing the embodiments disclosed in the present specification, when it is determined that detailed descriptions of related known technologies may obfuscate the gist of the embodiments disclosed in the present specification, the detailed description thereof may be omitted. In addition, the accompanying drawings are to aid in understanding of the embodiments disclosed herein, and the technical idea disclosed herein is not limited by the accompanying drawings, and changes included in the characteristics of the present disclosure may be understood to include equivalents or substitutes. The disclosure below is not intended to be limited to the form described or the specific field of the present disclosure, and it is contemplated that various alternative embodiments and modifications to the present disclosure are possible, whether (e.g., explicitly) set forth or implied herein. Those skilled in the art to which the present disclosure pertains may recognize that the form and details of the present disclosure may vary.

The present disclosure has been described with reference to various embodiments. However, as may be appreciated by those skilled in the art to which the present disclosure pertains, the various embodiments disclosed herein may be modified or implemented in various other ways without departing from the characteristics of the present disclosure. Accordingly, the following description is to be considered exemplary and is intended to teach those skilled in the art how to make and use various embodiments. It is to be understood that the forms of the disclosure illustrated and described herein are to be taken as representative embodiments. Equivalent elements, materials, processes, or steps may be substituted for those exemplified representatively and described herein. The words “including”, “comprising”, “incorporating”, “consisting of”, “have”, “is”, and the like, when used in describing this disclosure, may be construed in a non-exclusive manner, that is, the words may be construed to allow for the inclusion of items, components, or elements that are not explicitly listed. In addition, references to the singular may be construed as including references to the plural.

In addition, the various embodiments disclosed herein are to be taken in an illustrative and explanatory sense and should not be construed as limiting the scope of the present disclosure. Any references to joining (for example, attached, affixed, coupled, connected, and the like) are used to facilitate understanding of the present disclosure and do not constitute any limitation as to the location, orientation, or use of any component or method disclosed herein. Therefore, when the joining references exist, they may be interpreted broadly. Moreover, these joining references do not imply that two or more elements are directly connected to each other. Any numeric terms, such as “first”, “second”, “third”, “primary”, “secondary”, “main”, or any other generic or numeric terms, are to be taken as identifiers to aid in understanding the various components, configurations, variations, or modifications of the present disclosure and do not imply any limitation as to any component, configuration, variation, or modification or any order or preference with respect to them. That is, these expressions may be used to describe various components, but the components are not limited by these expressions. These expressions are used for the purpose of distinguishing one component from another.

The terms “module” and “part” used for components in the following description are given or used interchangeably for the convenience of writing the specification and do not have distinct meanings or roles in themselves.

When a component is “connected” or “linked” to another component, it may be understood that it may be directly connected or linked to that other component, but there may also be other components in between. On the other hand, when it is said that a component is “directly connected” or “directly linked” to another component, it may be understood that there are no other components in between.

In addition, any number of components or a variety of components may be included in any of the configurations described herein. The components may include any combination of features described herein and may be arranged in any of the various configurations described herein. The concepts of the structure and arrangement of the components of the present disclosure, as well as their use and operation, may be applied to any number of embodiments in any combination, not just the specific embodiments discussed herein. Embodiments including those having various features in various arrangements are described below with reference to the drawings.

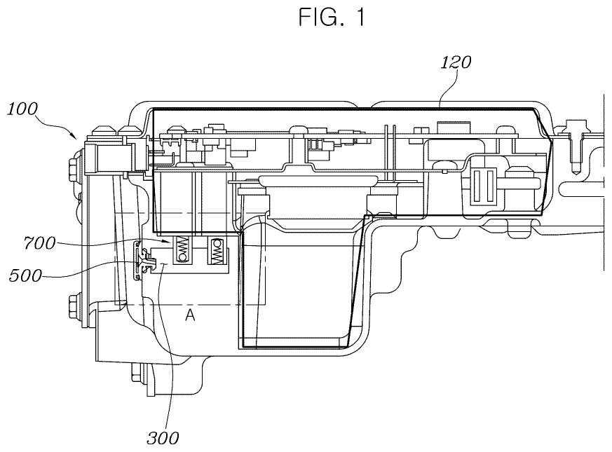

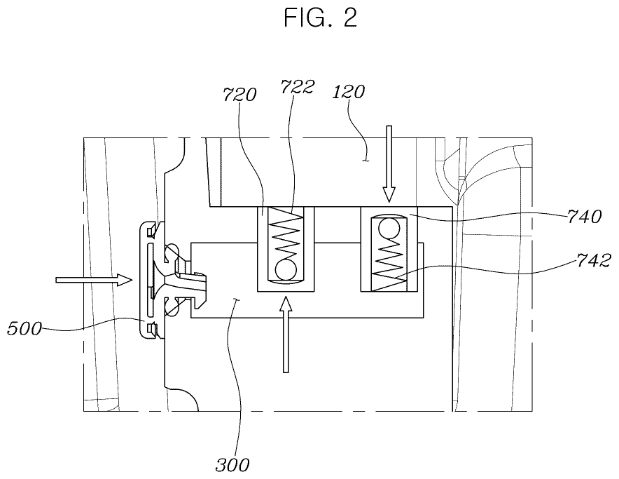

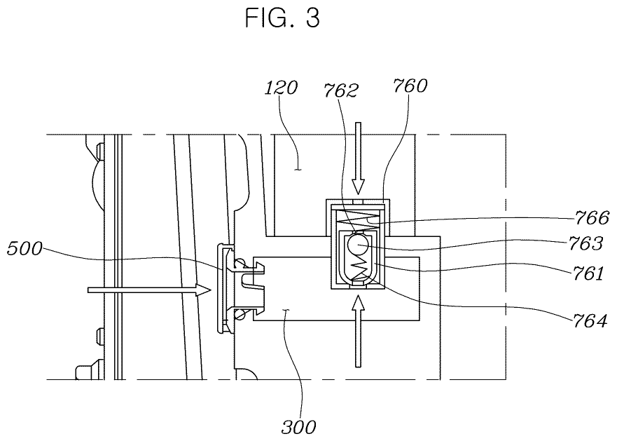

FIG. 1 is a drawing showing a power conversion device according to an embodiment, FIG. 2 is an enlarged drawing of part A of the power conversion device according to an embodiment shown in FIG. 1, and FIG. 3 is a drawing showing a power conversion device according to another embodiment.

Hereinafter, various embodiments disclosed in the present specification may be described in detail with reference to the accompanying drawings. Regardless of the drawing numbers, (e.g., identical or) similar components are given the same reference numbers and redundant descriptions thereof may be omitted.

Inside power conversion devices such as inverters, the temperature and pressure increase due to the heat generated during the operation of power conversion components, causing air to be discharged. Conversely, air is drawn in when the components are not operating. During this process, temperature changes may cause condensation, which may damage power conversion components and circuits, leading to device performance degradation and failure. Therefore, effective temperature and pressure management techniques may be useful to prevent condensation and maintain device reliability and performance.

In order to secure the durability of the power conversion components inside the power conversion device, it is useful to secure waterproof and dustproof performance and (e.g., at the same time) to prevent condensation inside the power conversion device by limiting fluid exchange with the outside. To this end, the present disclosure provides a method to minimize condensation by allowing fluid to move between the power conversion components and the outside (e.g., only) when the pressure reaches no less than a (e.g., specific) threshold.

Meanwhile, in order to explain the power conversion device, an inverter is used as an example below, but it may also be applied to various types of power conversion devices such as converters, rectifiers, UPS, voltage regulators, and similar devices in addition to inverters.

The power conversion device of the present disclosure may be applied to a vehicle. For example, in the power system of an electric vehicle, an inverter is a device that converts direct current power stored in a battery into alternating current power that may drive a vehicle motor and improve the performance of the vehicle through efficient power conversion. These inverters may benefit from being protected from temperature changes and vibrations that may occur in the vehicle's driving environment and, in particular, may be able to prevent condensation caused by heat and pressure changes inside the inverter.

Temperature and pressure may change (e.g., rapidly) in a vehicle environment, which may lead to condensation inside power conversion devices such as inverters. For example, when the outside temperature drops sharply and the temperature inside the inverter is relatively high, moisture may condense on cold surfaces, causing condensation. In addition, condensation may also occur due to the cooling water flowing inside the power conversion device. This condensation may cause damage to the power conversion components and circuits and eventually cause the performance of the power conversion device to deteriorate and fail. Therefore, temperature and pressure management technology that may minimize the occurrence of condensation may be useful in power conversion devices applied to vehicles.

Therefore, when the power conversion device of the present disclosure is applied to a vehicle, the temperature and pressure difference inside the inverter may be managed, through a design including a chamber 300 that blocks an internal space 120 of the housing 100 from the outside, and a valve 700 that controls the fluid flow between the internal space 120 and the outside air. In more detail, when the differential pressure inside the inverter increases above a (e.g., certain) level, an air flow between the outside and the internal space 120 may be controlled by selectively opening and closing the valve 700. This may prevent excessive condensation and safely protect the inverter. In addition, the valve 700 may be automatically opened and closed to prevent the differential pressure from becoming (e.g., excessively) large, thereby controlling the air flow to maintain the pressure balance inside the inverter.

In addition, vibration and shock in the vehicle environment also may be considered. These external factors may cause damage to the internal components of the inverter, so a durable design, in addition to waterproof and dustproof performance, may be useful. The configuration of the filter 500 and valve 700 presented in the present disclosure may effectively operate, even in various driving environments of a vehicle, thereby blocking foreign substances or moisture from entering the inverter and maintaining the durability of the power conversion component.

Therefore, the following describes an inverter applicable to a vehicle as a (e.g., representative) example to help in understanding the disclosure. In addition to the inverter, it may be applied to various power conversion devices, and beyond vehicles, it may be used in various fields such as power generation systems, electric energy backup systems, high-speed railways, ships, aircraft, and/or the like.

With reference to the drawings, a power conversion device applicable to various fields including vehicles is described in detail.

First, with reference to FIG. 1, a power conversion device according to various embodiments of the present disclosure is described.

In an embodiment, the power conversion device may include a housing 100, a chamber 300, a filter 500, and a valve 700. The housing 100 may have a built-in power conversion component in the internal space 120 and may include a chamber 300 provided to be separated from the internal space 120 of the housing 100. In addition, the filter 500 may be coupled to a (e.g., one) side of the chamber 300 to block the inflow of moisture and foreign substances from the outside into the chamber 300. In addition, the valve 700 may be provided between the internal space 120 of the housing 100 and the chamber 300 to block the communication between the internal space 120 of the housing 100 and the outside and be selectively opened and closed according to the differential pressure between the internal space 120 of the housing 100 and the chamber 300.

Meanwhile, the filter 500 described in an embodiment is described as a membrane filter in the form of a thin film configured to filter substances through microscopic holes to remove foreign substances and the like. When it is possible to secure waterproof or dustproof performance of the internal space 120 of the housing 100 by preventing a large amount of moisture or foreign substances from entering the chamber 300, various types of filters, such as cartridge-type filters and bag-type filters, may be applied in addition to the membrane filter.

In addition, the valve 700 described in an embodiment is a bypass valve that allows air to pass in (e.g., only) one direction under conditions in which the pressure reaches no less than a (e.g., specific) threshold. However, in addition to the bypass valve, various types of valves such as a sliding gate valve, a valve that rotates a disk, and a valve that uses an electric signal may be applied.

In an embodiment, as shown in FIG. 1, the internal space 120 in which the power conversion component is built-in may be provided in the housing 100, and the chamber 300 connecting the internal space 120 and the outside may be provided. In addition, as shown in part A of FIG. 1, the filter 500 may be provided on a left side near the outside, and the valve 700 may be provided between the chamber 300 and the internal space 120. However, this configuration is exemplary, and various types of power conversion components and chambers 300 may be considered for arrangement within the power conversion device, and the filter 500 and valve 700 may also be combined with the chamber 300 at various locations or provided between the internal space 120 of the housing 100 and the chamber 300.

In an embodiment, the valve 700 provided between the internal space 120 of the housing 100 and the chamber 300 may include at least one of elastic bodies 722 and 742, 764 and 766. In this case, the elastic bodies 722, 742, 764, and 766 may be configured to operate under conditions different from one another depending on the differential pressure between the internal space 120 of the housing 100 and the chamber 300, thereby allowing temporary communication between the inner space of the housing 100 and the outside. Further, foreign substances or a large amount of moisture from the outside may not enter the power conversion component, so the foreign substances or moisture may be filtered primarily through the filter 500 and then filtered secondarily by blocking the communication between the chamber 300 and the internal space 120 through the valve 700.

However, in an embodiment, when the air is (e.g., completely) blocked to the internal space 120 of the housing 100 in which the power conversion component is built-in, the pressure difference between the inside and outside of the housing 100 may become excessive, thereby posing a risk of potentially causing damage to the seal and the like and making it difficult to ensure waterproof and dustproof performance. Meanwhile, when communication between the internal space 120 of the housing 100, where the power conversion component is located, and the outside is freely established, direct damage to the power conversion component may occur due to condensation or foreign substances. However, when the communication is (e.g., completely) blocked, the seal may become damaged, making it even more difficult to ensure waterproof and dustproof performance. Therefore, it is useful to secure an appropriate level of pressure difference and waterproof and dustproof performance.

Therefore, in an embodiment, the above problem may be solved by using the valve 700 including at least one of the elastic bodies 722, 742, 764, and 766. In more detail, the valve 700 is configured to operate by the elastic force of at least one of the elastic bodies 722, 742, 764, and 766. When the elastic force is greater than the differential pressure between the internal space 120 of the housing 100 and the chamber 300, at least one of the elastic bodies 722, 742, 764, and 766 expands to close the valve 700, and when the elastic force is less than the differential pressure, at least one of the elastic bodies 722, 742, 764, and 766 contracts to open the valve 700. By controlling the elastic force of at least one of the elastic bodies 722, 742, 764, and 766 included in the valve 700, an appropriate pressure difference between the internal space 120 of the housing 100 and the chamber 300 that may be communicated with the outside may be maintained, and excessive moisture or foreign substances may be prevented from entering.

Next, a unidirectional (e.g., one-way) valve 700 according to various embodiments of the present disclosure may be described with reference to FIG. 2.

In an embodiment, the valve 700 may be provided with a plurality of valves, and each of the valves may allow the fluid to flow in (e.g., only) one direction. Each valve allows fluid to flow in (e.g., only) one direction, so the valves that are different from one another may be arranged in various orientations to ensure differing flow directions. This design may maintain a pressure balance between the internal space 120 of the housing 100 and chamber 300.

In an embodiment, the elastic bodies 722, 742, 764, and 766 are individually provided in each of the plurality of valves, as described above. Each elastic body 722, 742, 764, and 766 may have a contracting direction different from the others, allowing each valve to open in a different direction. For a more effective application, bypass valves may be used. The plurality of valves may be arranged between the chamber 300 and the internal space 120, allowing them to open in a direction toward the chamber 300 and in a direction toward the internal space 120 of the housing 100.

In more detail, in an embodiment, the valve 700 may include a first valve 720 and a second valve 740, with the first valve 720 and the second valve 740 including a first elastic body 722 and a second elastic body 742, respectively. The first elastic body 722 and the second elastic body 742 may contract in different directions, causing the opening directions of the first valve 720 and the second valve 740 to differ from each other.

In an embodiment, when the first valve 720 opens, fluid may flow from the chamber 300 toward the internal space 120 of the housing 100. Conversely, when the second valve 740 opens, fluid may flow from the internal space 120 of the housing 100 toward the chamber 300.

In an embodiment, whether the first valve 720 and the second valve 740 open may depend on the differential pressure between the internal space 120 of the housing 100 and the chamber 300. In more detail, when the differential pressure between the chamber 300 and the internal space 120 of the housing 100 is greater than the elastic force of the first elastic body 722, the first valve 720 opens, allowing the fluid to flow from the chamber 300 to the internal space 120 of the housing 100. Similarly, when the differential pressure is greater than the elastic force of the second elastic body 742, the second valve 740 opens, allowing the fluid to flow from the internal space 120 of the housing 100 to the chamber 300.

In an embodiment, the first valve 720 and the second valve 740 may have different opening differential pressures due to the differing elastic forces of the first elastic body 722 and the second elastic body 742. Specifically, the elastic bodies 722, 742, 764, and 766 used in the present disclosure may be springs, and the elastic force that opens due to differential pressure may be adjusted by setting a different spring constant for each spring. For example, when the elastic modulus of the first elastic body 722 is set to be greater than that of the second elastic body 742, the flow of fluid from the chamber 300 to the internal space 120 of the housing 100 may be more difficult than the flow of fluid from the internal space 120 of the housing 100 to the chamber 300. In this case, since the elastic coefficient of the first elastic body 722 is set to be greater than that of the second elastic body 742, a differential pressure greater than that (e.g., required) to open the second valve 740 may be (e.g., required) to open the first valve 720.

Hereinafter, an integrated valve 760 according to various embodiments of the present disclosure may be described with reference to FIG. 3.

In an embodiment, an integrated valve 760 may be used as a valve applicable to the present disclosure, in addition to the (e.g., one-way) valve 700. The integrated valve 760 is a valve that may open in opposite directions and may include a plurality of elastic bodies 722, 742, 764, and 766. Each of the elastic bodies 722, 742, 764, and 766 may have different contracting directions.

In an embodiment, the integrated valve 760 may be provided with an introduction elastic body 766 and a discharge elastic body 764. The introduction elastic body 766 may be an elastic body that is configured to contract when the fluid is introduced into the internal space 120 of the housing 100, while the discharge elastic body 764 may be an elastic body that is configured to contract when the fluid is discharged from the internal space 120 of the housing 100. Accordingly, when the introduction elastic body 766 contracts, the fluid may flow from the chamber 300 toward the internal space 120 of the housing 100, while when the discharge elastic body 764 contracts, the fluid may flow from the internal space 120 of the housing 100 toward the chamber 300.

In an embodiment, both the introduction elastic body 766 and the discharge elastic body 764 contract according to the differential pressure between the internal space 120 of the housing 100 and the chamber 300. The introduction elastic body 766 and the discharge elastic body 764 may have different elastic forces, so the differential pressures at which they contract may also differ. As with the (e.g., one-way) valve 700 described above, in the case of the integrated valve 760, the elastic coefficients of the multiple elastic bodies 722, 742, 764, and 766 applied inside may be set differently from each other, thereby appropriately setting the pressure value at which the fluid may be introduced or discharged into the internal space 120 of the housing 100.

For example, in an embodiment, when the elastic modulus of the introduction elastic body 766 is greater than that of the discharge elastic body 764, it may be more difficult for the fluid to be introduced into the internal space 120 of the housing 100 than for the fluid to be discharged from the internal space 120. By adjusting the elastic coefficient of the elastic bodies 722, 742, 764, and 766 in this way, the waterproof or dustproof performance of the power conversion component located in the internal space 120 of the housing 100 may be secured, and the pressure balance between the inside and outside of the housing 100 may be maintained.

In an embodiment, when the differential pressure between the chamber 300 and the internal space 120 of the housing 100 is greater than the elastic force of the introduction elastic body 766, the introduction elastic body 766 contracts, and the fluid flows into the internal space 120 of the housing 100. Similarly, when the differential pressure between the chamber 300 and the internal space 120 of the housing 100 is greater than the discharge elastic body 764, the discharge elastic body 764 contracts, and the fluid flows into the chamber 300.

In an embodiment, as shown in FIG. 3, a regulator 761 is provided inside the integral valve 760, and the regulator 761 may be in contact with an introduction elastic body 766 fixed to the integral valve 760. Specifically, one end of the introduction elastic body 766 is fixed to a side near the internal space 120 of the housing 100 in the integral valve 760, and an opposite end may be in contact with the regulator 761. In addition, the regulator 761 may have a (e.g., one) side in contact with an introduction elastic body 766 fixed to an integral valve 760 and an opposite side connected to the chamber 300, while the discharge elastic body 764 may be coupled to the inside of the regulator 761.

In an embodiment, the regulator 761 may include an adjustment hole 762, an adjustment ball 763, and a discharge elastic body 764. The adjustment hole 762 of the regulator 761 is provided in a direction facing the internal space 120 of the housing 100, allowing the fluid inside the integrated valve 760 to flow into and out of the regulator 761. In addition, the adjustment ball 763 may open or close the adjustment hole 762 by coming into contact with it, depending on whether the introduction elastic body 766 or the discharge elastic body 764 contracts. In addition, the discharge elastic body 764 is connected to the adjustment ball 763 on a (e.g., one) side and fixed to the inside of the regulator 761 on the opposite side, allowing the adjustment ball 763 to pressurize the discharge elastic body 764 in the direction of contraction when the fluid flows from the outside into the inside of the regulator 761.

In an embodiment, when the introduction elastic body 766 contracts, since the fluid flows from the chamber 300 to the internal space 120 of the housing 100, the fluid may be introduced into the internal space 120 of the housing 100 through the space between the regulator 761 and the integrated valve 760 as the regulator 761 contracts the introduction elastic body 766 as a whole. In this case, the adjustment ball 763 may remain in a form that closes the adjustment hole 762 because the discharge elastic body 764 has not contracted.

In an embodiment, when the discharge elastic body 764 contracts, the fluid flows into the chamber 300, so the fluid from the internal space 120 of the housing 100 flows into the integrated valve 760 and further flows into the regulator 761 through the adjustment hole 762, so that the adjustment ball 763 may pressurize the discharge elastic body 764. In this case, the fluid may move into the space between the regulator 761 and the integrated valve 760 and flow to the chamber 300.

In an embodiment, when the differential pressure between the chamber 300 and the internal space 120 of the housing 100 is less than that of the discharge elastic body 764, the adjustment hole 762 is closed by the adjustment ball 763. Conversely, when the differential pressure is greater than that of the discharge elastic body 764, the discharge elastic body 764 may contract to open the adjustment hole 762.

Although the present disclosure has been shown and described with respect to various embodiments, without departing from the technical characteristics of the present disclosure as provided by the following claims, it may be apparent to those skilled in the art that the present disclosure may be improved and changed in various ways.

What is claimed is:

1. A power conversion device comprising:
a housing with an internal space, wherein a power conversion component is built into the internal space;
a chamber provided separate from the internal space of the housing;
a filter coupled to a side of the chamber and configured to block moisture and foreign substances from entering the chamber from the outside; and
a valve provided between the internal space of the housing and the chamber to block communication between the internal space of the housing and the outside, and the valve is configured to be selectively opened and closed by a differential pressure between the internal space of the housing and the chamber.

2. The power conversion device of claim 1, wherein the valve comprises:
at least one elastic body,
wherein the elastic body is configured to operate under conditions different from one another depending on the differential pressure between the internal space of the housing and the chamber, thereby allowing temporary communication between the internal space of the housing and the outside.

3. The power conversion device of claim 2, wherein the valve is configured to be operated by an elastic force of the elastic body, such that when the elastic force is greater than the differential pressure, the elastic body expands and closes the valve, and when the elastic force is less than the differential pressure, the elastic body contracts and opens the valve.

4. The power conversion device of claim 2, wherein the valve comprises:
a plurality of valves, wherein when each of the plurality of valves are the same, each valve allows fluid to flow in one direction, and wherein when each valve of the plurality of valves are different from one another, each valve permits the fluid to flow in different directions.

5. The power conversion device of claim 4, wherein each of the plurality of valves is provided with an elastic body, wherein each elastic body contracts in a different direction, thereby causing each of the valves to open in a different direction.

6. The power conversion device of claim 4, wherein the plurality of valves comprise:
a first valve and a second valve, the first valve including a first elastic body and the second valve including a second elastic body, wherein the first valve contracts in a different direction than the second valve, thereby causing the first valve to open in a different direction than the second valve.

7. The power conversion device of claim 6, wherein, in response that the first valve is open, the fluid flows from the chamber toward the internal space of the housing, and in response that the second valve is open, the fluid flows from the internal space of the housing toward the chamber.

8. The power conversion device of claim 6, wherein the first valve opens in response to the differential pressure between the chamber and the internal space of the housing being greater than an elastic force of the first elastic body, and the second valve opens in response to the differential pressure being greater than an elastic force of the second elastic body.

9. The power conversion device of claim 8, wherein the first valve and the second valve have different differential pressures at which they open because elastic forces of the first elastic body is different than the elastic force of the second elastic body.

10. The power conversion device of claim 3, wherein the valve is an integral valve capable of opening in opposite directions, wherein the integral valve has a plurality of elastic bodies provided inside, and wherein each elastic body of the plurality of elastic bodies has a different direction of contraction.

11. The power conversion device of claim 10, wherein the integral valve is provided with an introduction elastic body and a discharge elastic body, wherein fluid flows from the chamber toward the internal space of the housing in response to the introduction elastic body contracting, and wherein the fluid flows from the internal space of the housing toward the chamber in response to the discharge elastic body contracting.

12. The power conversion device of claim 11, wherein the introduction elastic body and the discharge elastic body contract at differential pressures between the internal space of the housing and the chamber, and the differential pressures at which the introduction elastic body and the discharge elastic body contract differ due to different elastic forces of the introduction elastic body and the discharge elastic body.

13. The power conversion device of claim 11, wherein, in response to the differential pressure between the chamber and the internal space of the housing being greater than an elastic force of the introduction elastic body, the introduction elastic body contracts, allowing the fluid to flow into the internal space of the housing, and wherein, in response to the differential pressure being greater than the discharge elastic body, an elastic force of the discharge elastic body contracts, allowing the fluid to flow into the chamber.

14. The power conversion device of claim 13, wherein a regulator is provided inside the integral valve, a side of the regulator is in contact with the introduction elastic body fixed to the integral valve, an opposite side of the regulator is connected to the chamber, and the discharge elastic body is included inside the regulator.

15. The power conversion device of claim 14, wherein the regulator further comprises:
an adjustment hole provided in a direction facing the internal space of the housing to allow fluid inside the integral valve to enter and exit the regulator; and
an adjustment ball provided inside the regulator, in contact with the adjustment hole, to open and close the adjustment hole by contraction of the introduction elastic body or the discharge elastic body,
wherein the discharge elastic body has an end connected to the adjustment ball and an opposite end fixed to inside of the regulator.

16. The power conversion device of claim 15, wherein, in response to fluid inside the integral valve being introduced into the regulator, the adjustment ball pressurizes the discharge elastic body, causing the discharge elastic body to contract.

17. The power conversion device of claim 15, wherein, in response to the introduction elastic body contracting, the adjustment hole is closed by the adjustment ball, whereas in response to the discharge elastic body contracting, the adjustment hole is opened.

18. The power conversion device of claim 15, wherein, in response to the differential pressure between the chamber and the internal space of the housing being less than the elastic force of the discharge elastic body, the adjustment hole is closed by the adjustment ball, whereas in response to the differential pressure between the chamber and the internal space of the housing being greater than the elastic force of the discharge elastic body, the discharge elastic body contracts and the adjustment hole is opened.

19. The power conversion device of claim 1, wherein the filter communicates with the outside, and as outside air is introduced into the chamber through the filter, a pressure difference is provided between the internal space of the housing and the chamber.

20. The power conversion device of claim 1, wherein the chamber is located inside the housing, the filter is coupled to a side of the chamber facing the outside, and the valve is coupled to an opposite side of the chamber facing the internal space of the housing.
